(19) United States
(12) Patent Application Publication
(10) Pub. No.: US 2004/0094797 A1
(43) Pub. Date: May 20, 2004

(54) MOS transistor having short channel and manufacturing method thereof

(76) Inventors: Il-Yong Park, Daejeon (KR); Sang-Gi Kim, Daejeon (KR); Byoung-Gon Yu, Daejeon (KR); Jong-Dae Kim, Daejeon (KR); Tae-Moon Roh, Daejeon (KR); Dae-Woo Lee, Daejeon (KR); Yil-Suk Yang, Daejeon (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/414,654

(22) Filed: Apr. 16, 2003

(30) Foreign Application Priority Data
Nov. 18, 2002 (KR) 2002-71498

(51) Int. Cl. H01L 29/76; H01L 29/94; H01L 27/12; H01L 27/01

(52) U.S. Cl. 257/327; 257/328; 257/349

(57) ABSTRACT

The MOS transistor of the present invention is manufactured by a conventional complementary MOS transistor technology. In the manufacturing method of the MOS transistor having nanometer dimensions, a gate having dimensions at a nanometer scale can be formed through control of the width of spacers instead of with a specific lithography technology. The doped spacers are used for forming source/drain extension regions having an ultra-shallow junction, thereby avoiding damage on the substrate caused by ion implantation. In addition, a dopant is diffused from the doped space into a semiconductor substrate through annealing to form the source/drain extension regions having an ultra-shallow junction.

### CROSS REFERENCE TO RELATED APPLICATION

This application is based on Korea Patent Application No. 2002-71498 filed on Nov. 18, 2002 in the Korean Intellectual Property Office, the content of which is incorporated herein by reference.

### BACKGROUND OF THE INVENTION

(a) Field of the Invention

The present invention relates to a MOS (metal oxide semiconductor) transistor and a manufacturing method thereof. More specifically, the present invention relates to a MOS transistor with a short channel having submicron or nanometer dimensions, and a manufacturing method thereof.

(b) Description of the Related Art

As semiconductor devices have been getting more highly integrated in recent years, technologies for reducing the chip size and refining the fabrication process have been developed. Particularly, the technology for forming a channel of the MOS transistor at a nanometer scale is in the spotlight.

U.S. Pat. No. 6,372,589 (dated Apr. 16, 2000), for example, discloses a method for reducing the junction depth of source/drain extension regions in forming source/drain regions of a MOS transistor. Namely, the method involves depositing a polysilicon gate, forming doped spacers on the sidewall of the polysilicon gate, and annealing the doped spacers to form an ultra-shallow junction, thereby reducing a short channel effect caused as an adverse effect in formation of a channel having nanometer dimensions.

U.S. Pat. No. 6,387,758 (dated on May 14, 2002) also discloses a method of using a vertical channel to form a nanometer-length channel by control of the film thickness so as to form the channel having nanometer dimensions.

The present invention adapts these prior art technologies to provide a MOS transistor with a short channel having nanometer dimensions and a manufacturing method thereof.

Now, a description will be given as to a MOS transistor according to prior art with reference to the accompanying drawings.

FIG. 1 is a cross-sectional view of the MOS transistor according to prior art. As illustrated in FIG. 1, source/drain regions 11 and 12 formed on a semiconductor substrate 1 include source/drain extension regions 13 and 14.

The source/drain extension regions 13 and 14 are formed as an ultra-shallow junction to minimize the short channel effect caused in the MOS transistor with a channel having submicron or nanometer dimensions. The MOS transistor shown in FIG. 1 includes the source/drain regions 11 and 12 for source and drain, and source/drain silicide layers 21 and 22 formed on the source/drain regions 11 and 12, respectively. The source/drain regions 11 and 12 are deeper than the source/drain extension regions 13 and 14, and the source/drain silicides 21 and 22 are formed on the source/drain regions 11 and 12 by junctions, thereby reducing the contact resistance of the MOS transistor.

A gate electrode 17 comprised of polysilicon is formed on a gate insulating layer 15 formed on the semiconductor substrate 1, and a gate silicide layer 23 for contact is formed on the gate electrode 17. The MOS transistor is electrically isolated from other ICs by way of STI (Shallow Trench Isolation) regions 19. Spacers 16 comprised of nitride are formed on either sidewall of the gate. The self-aligned source/drain extension regions 13 and 14 can be formed through the spacers 16. Between the sidewall of the gate polysilicon layer 17 and the spacers 16 are formed buffer layers 18.

The formation of a fine pattern is of a great importance in forming a channel having nanometer dimensions in the MOS transistor. But it is difficult to form a pattern having a length of several nanometers by the current lithography technology. Moreover, the junction depths of the source/drain regions are required to be considerably small, which is necessary for reducing the short channel effect. It is, however, impossible to manufacture a transistor having nanometer dimensions by using the conventional MOS transistor technologies, especially the old style MOS process involving a lot of design regulations.

Contrarily, the present invention provides a manufacturing method for forming a gate having nanometer dimensions without using the lithography method, and it controls the length of the gate simply by regulating the film thickness and using an etching technology. Also, the manufacturing method of the present invention forms an ultra-shallow junction using a doped oxide layer to reduce the short channel effect.

### SUMMARY OF THE INVENTION

It is an advantage of the present invention to overcome the limitations of the conventional lithography technology, and to provide a MOS transistor with a channel region having nanometer dimensions and a manufacturing method thereof by using spacers to form a pattern having nanometer dimensions and forming source/drain extension regions having a shallow junction using a doped oxide layer.

In one aspect of the present invention, there is provided a MOS transistor including: a semiconductor substrate; shallow trench isolation regions formed on either side of the semiconductor substrate and used for separation of elements; source/drain regions being in contact with both sides of the shallow trench isolation regions and extending towards a center; spacers being in contact with the source/drain regions and having a predetermined depth inside the semiconductor substrate, the spacers being apart from each other at a predetermined distance; a polysilicon layer filled between the spacers and functioning as a gate electrode; a gate insulating layer formed to surround the bottom part of the polysilicon layer; and source/drain extension regions formed by implanting ions from each spacer into the semiconductor substrate and being in contact with the source/drain regions. The length of the polysilicon layer is controlled by the distance between the spacers.

In another aspect of the present invention, there is provided a method for manufacturing the MOS transistor that includes: (a) forming shallow trench isolation regions, used for separation from other elements, on either side of a semiconductor substrate comprised of silicon, and implanting impurities to form source/drain regions being in contact with each shallow trench isolation region and extending towards a center; (b) depositing a first oxide layer on a whole surface, etching a defined region of the center in a predetermined depth inside the semiconductor substrate, and forming spacers on a sidewall of each source/drain region; (c) further etching the semiconductor substrate between the spacers to form a gate insulating layer; (d) performing annealing on the whole resultant material, and implanting impurities from the spacers into the semiconductor substrate to form source/drain extension regions beneath each spacer, the source/drain extension regions being a shallow junction to the source/drain regions; (e) depositing a polysilicon layer between the spacers to form a gate electrode; and (f) depositing a second oxide layer on the whole surface, etching a region to be source and drain electrodes, and forming source and drain electrodes in the etched region through metallation.

The above-stated MOS transistor according to the present invention includes spacers formed from a doped oxide layer in a gate region to form a gate having dimensions at a nanometer length scale, and source/drain extension regions of ultra-shallow junctions formed through annealing, so that the MOS transistor having dimensions at a nanometer length scale can be manufactured by using the conventional complementary MOS transistor technology.

### BRIEF DESCRIPTION OF THE DRAWINGS

The accompanying drawings, which are incorporated in and constitute a part of the specification, illustrate an embodiment of the invention, and, together with the description, serve to explain the principles of the invention:

FIG. 1 is a cross-sectional view of a MOS transistor according to prior art;

FIGS. 2a to 2h show a process for manufacturing a MOS transistor according to a first embodiment of the present invention; and

FIGS. 3a to 3g show a process for manufacturing a MOS transistor according to a second embodiment of the present invention.

### DETAILED DESCRIPTION OF THE PREFERRED EMBODIMENTS

In the following detailed description, only the preferred embodiment of the invention has been shown and described, simply by way of illustration of the best mode contemplated by the inventor(s) of carrying out the invention. As will be realized, the invention is capable of modification in various obvious respects, all without departing from the invention. Accordingly, the drawings and description are to be regarded as illustrative in nature, and not restrictive.

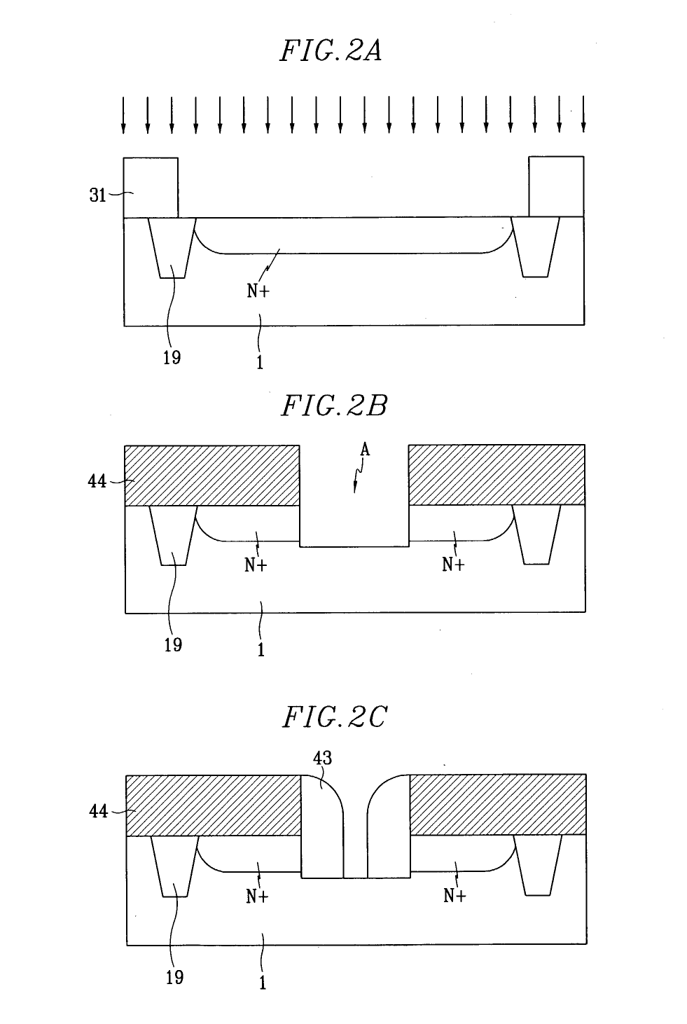

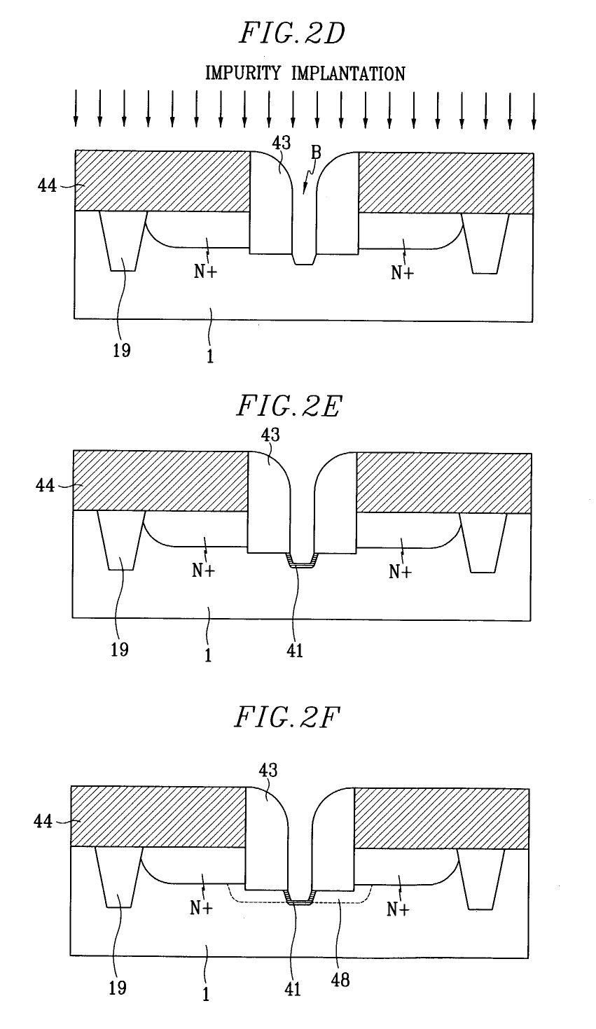

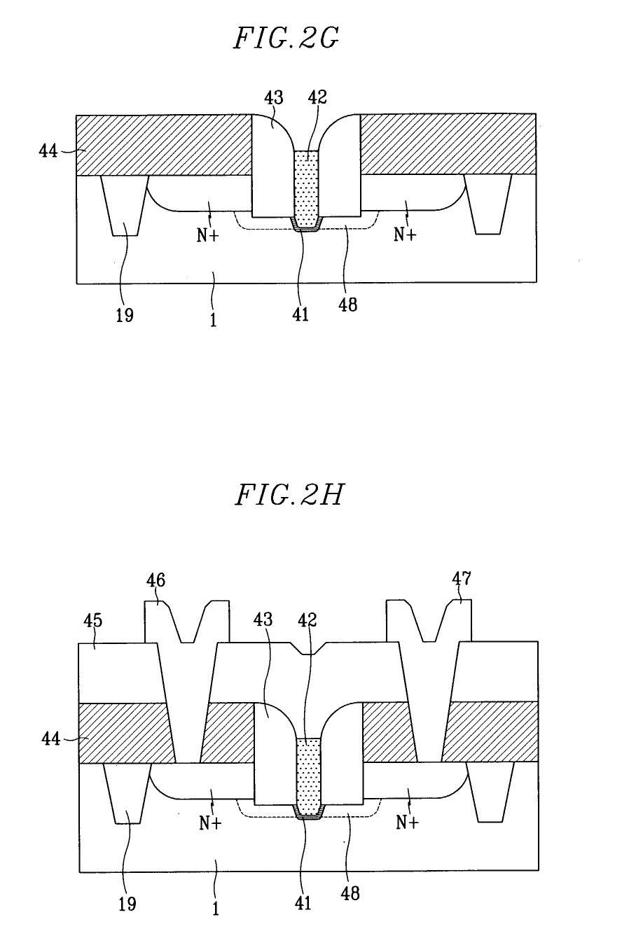

FIGS. 2a to 2h are sequential diagrams showing a process for manufacturing a MOS transistor according to a first embodiment of the present invention. FIG. 2h is a cross-sectional view of the completed MOS transistor.

Now, a description will be given as to the structure of the MOS transistor according to the first embodiment of the present invention with reference to FIG. 2h.

Referring to FIG. 2h, STI regions 19 for separating elements are formed on either side of a semiconductor substrate 1, and source/drain regions N+ for source and drain extend towards the center from the STI regions 19. In the source/drain regions N+, spacers 43 are formed to abut the corresponding source/drain regions N+. The spacers 43 are apart from each other at a predetermined distance. In the present invention, the distance between the spacers 43 is controlled at a nanometer scale. A polysilicon layer 42 for forming a gate is filled between the spacers 43. The spacers 43 are formed as deep as or deeper than the source/drain regions N+. A gate oxide layer 41 underlying the spacers 43 is formed to surround the polysilicon layer 42. Beneath the source/drain regions N+ and the spacers 43 are formed source/drain extension regions 48, which form a shallow junction to the source/drain regions N+ and surround the bottom part of the spacers 43. The source/drain extension regions 48 are then in contact with the gate oxide layer 41. First and second oxide layers 44 and 45 are sequentially formed on the whole surface to expose a portion of the source/drain regions N+ to be source and drain electrodes. In the exposed source/drain regions N+, drain and source electrodes 46 and 47 are formed.

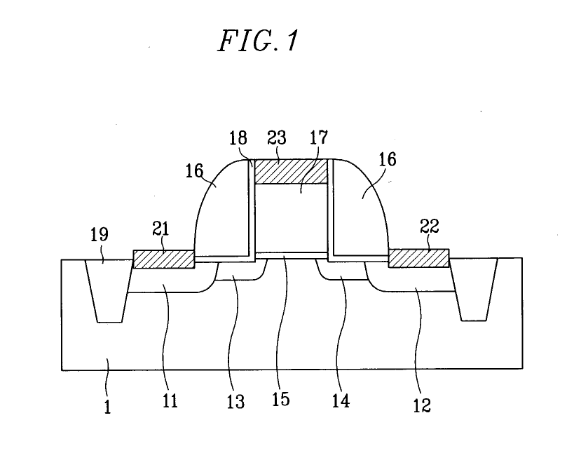

Even though it is not illustrated in the figure, the silicide layer of FIG. 1 can be additionally formed on the source/drain regions N+ and the polysilicon layer 42 so as to reduce contact resistance.

In the first embodiment of the present invention, the length of the polysilicon layer 42 used as a gate electrode can be controlled at a nanometer scale by the distance between the spacers 43 formed in the gate region, and the source/drain extension regions 48 having an ultra-shallow junction are formed, as a result of which a MOS transistor with a channel having nanometer dimensions can be manufactured by the conventional complementary MOS transistor technology.

Next, a description will be given as to a method for manufacturing the MOS transistor according to the first embodiment of the present invention with reference to FIGS. 2a to 2h.

Referring to FIG. 2a, the STI regions 19 for isolation from other elements are formed on either side of the semiconductor substrate 1. With a mask pattern 31 positioned, impurities are implanted to form N+ regions in contact with the STI regions 19. For a p-type MOS transistor, p-type impurities are implanted to form a P+ region. The N+ regions have a depth as known to those skilled in the art of the complementary MOS transistor technology.

Referring to FIG. 2b, the oxide layer 44 is deposited on the whole surface and a mask pattern is formed in a defined region to remove the oxide layer deposited on the mask pattern. The remaining oxide layer pattern 44 is used as a mask in etching the N+ regions and the semiconductor substrate 1 to form a space (called “a trench”) as denoted by “A” of FIG. 2b. The etching depth of the N+ regions is equal to or greater than the junction depth of the N+ regions. As a result, spacers are formed in the space A and source/drain extension regions are formed through the spacers.

Referring to FIG. 2c, a doped oxide layer is deposited to cover the silicon pattern of the oxide layer 44 and the N+ regions, and the spacers 43 are formed on the sidewall of the trench A by dry etching. The distance between the spacers 43 formed on the sidewall of the trench is controlled by the film thickness of the doped oxide layer and the etching rate. In the embodiment of the present invention, the distance between the spacers 43 is controlled at a nanometer scale.

Referring to FIG. 2d, ion implantation is performed to implant impurities for a control of the threshold voltage into the silicon region of the exposed semiconductor substrate 1 between the spacers 43. The silicon region of the exposed semiconductor substrate 1 is a little more etched. The etching depth of the silicon region is slightly greater than the junction depth of the source/drain extension regions to be formed later.

Referring to FIG. 2e, the gate oxide layer 41 is formed in the exposed silicon region. The gate oxide layer 41 can be substituted with a high-k dielectric thin film of another kind.

Referring to FIG. 2f, annealing is adequately carried out on the whole resultant material to implant impurities from the spacers 43 comprised of the doped oxide layer into the silicon region of the semiconductor substrate 1, thereby forming the source/drain extension regions 48 beneath the spacers 43. The source/drain extension regions 48 are shallow junctions to the source/drain regions N+.

Referring to FIG. 2g, the polysilicon layer 42 is filled between the spacers 43 by deposition to form a gate electrode. By using an etch-back process, the deposited polysilicon layer 42 is etched out to make its top surface deeper than the spacers 43. Here, a mask is used lest the etch-back process should be performed on a portion for a gate pad.

Referring to FIG. 2h, the second oxide layer 45 is deposited on the whole surface and the source/drain regions are etched to expose the surface of the N+ regions, on which the drain and source electrodes 46 and 47 are formed by a general metallation process.

Consequently, a MOS transistor with a channel having dimensions at a nanometer scale can be manufactured using the conventional complementary MOS transistor technology by forming the spacers 43 comprised of a doped oxide in the gate region to form a gate having dimensions at the nanometer length scale, and performing annealing to form the source/drain extension regions 48 of an ultra-shallow junction.

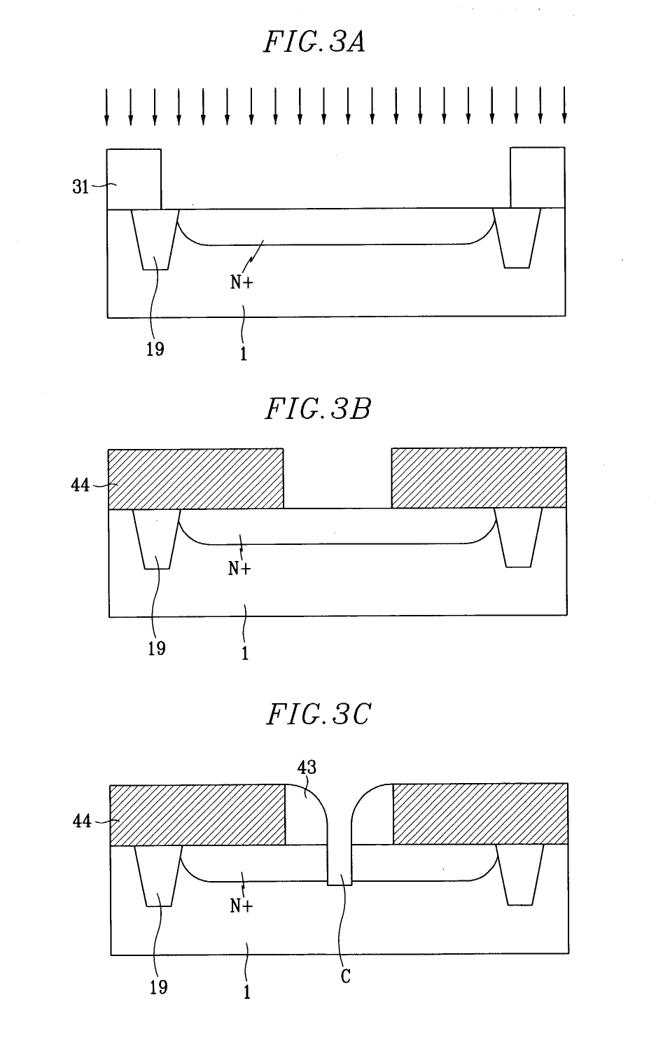

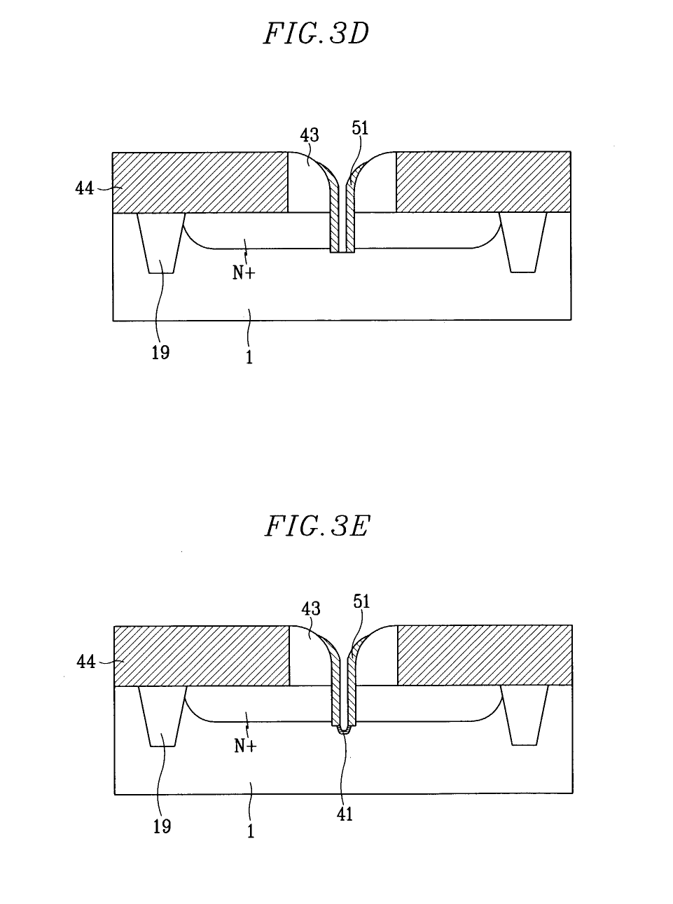

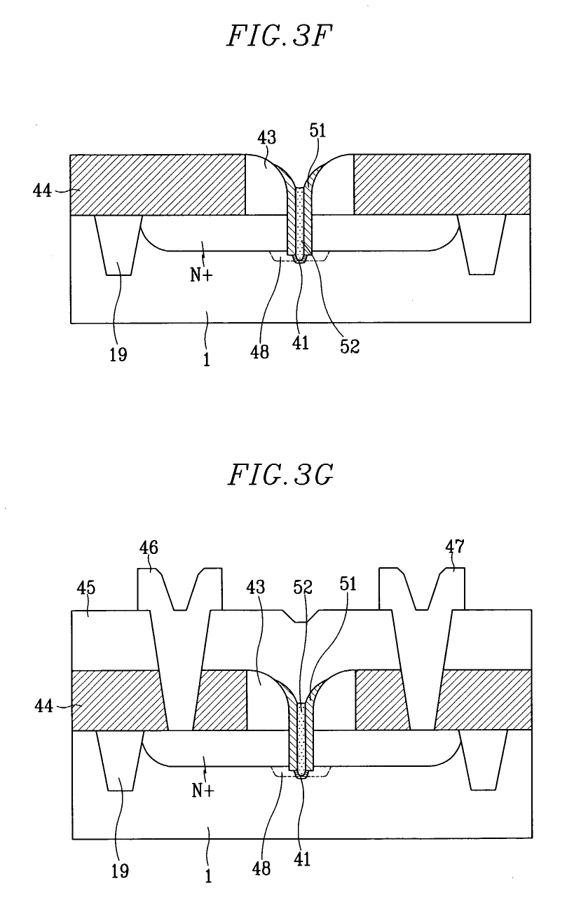

Next, a description will be given as to a method for manufacturing a MOS transistor according to a second embodiment of the present invention with reference to FIGS. 3a to 3g.

The MOS transistor according to the second embodiment of the present invention is characterized in that a double spacer is used to manufacture a MOS transistor with a channel having dimensions at the nanometer length scale. In the case of using the principle of the second embodiment, it is possible to manufacture a MOS transistor with a channel having dimensions at a lower nanometer length scale, compared with the first embodiment.

Referring to FIG. 3a, the STI regions 19 for isolation from other elements are formed on either side of the semiconductor substrate 1 comprised of silicon. With the mask pattern 31 positioned, impurities are implanted to form an N+ region between the two STI regions 19.

Referring to FIG. 3b, the first oxide layer 44 is deposited on the whole surface and a mask pattern is formed at a defined region to remove the oxide layer deposited on the mask pattern, thereby exposing a part of the N+ region.

Referring to FIG. 3c, an oxide layer is deposited all over the surface to cover the first oxide layer 44 and the exposed N+ region, and dry-etched to form spacers 43 on the sidewall of the first oxide layer 44. In this embodiment, the spacers 43 are called “first spacers”. Unlike the first embodiment, this embodiment forms no silicon trench region. Once the first spacers 43 comprised of the oxide layer are formed, the silicon region of the semiconductor substrate 1 is etched as deep as or deeper than the junction depth of the N+ region.

Referring to FIG. 3d, the doped oxide layer is deposited and then dry-etched to form second spacers 51.

Referring to FIG. 3e, the exposed silicon region between the second spacers 51 is slightly etched using the first oxide layer 44 and the first and second spacers 43 and 51 as a mask to form the gate oxide layer 41.

Referring to FIG. 3f, annealing is carried out on the whole resultant material to diffuse impurities from the second spacers 51 into the silicon region of the semiconductor substrate 1, thereby forming the source/drain extension regions 48. The space between the second spacers 51 is filled with the polysilicon layer 52 used as a gate electrode.

Referring to FIG. 3g, the second oxide layer 45 is deposited on the whole surface and the region for forming source and drain electrodes is etched out. Then metallation is carried out to form the drain and source electrodes 46 and 47.

In the manufacturing method of the second embodiment, the first or second spacers 43 or 51, the polysilicon layer 52 and the source/drain extension regions 48 are formed in a self-alignment manner without using a separate mask.

While this invention has been described in connection with what is presently considered to be the most practical and preferred embodiment, it is to be understood that the invention is not limited to the disclosed embodiments, but, on the contrary, is intended to cover various modifications and equivalent arrangements included within the spirit and scope of the appended claims.

In the MOS transistor and the manufacturing method thereof according to the present invention, a pattern having nanometer dimensions can be formed without using lithography technology, and source/drain regions of ultra-shallow junctions are formed for reducing the short channel effect. Particularly, the present invention utilizes the conventional complementary MOS transistor technology and thereby realizes a MOS transistor with a channel having dimensions at a nanometer scale and a circuit using the MOS transistor by the existing manufacturing process and design technologies.

What is claimed is:

1. A MOS (metal oxide semiconductor) transistor comprising:
a semiconductor substrate;
shallow trench isolation regions formed on either side of the semiconductor substrate and used for separation of elements;
source/drain regions being in contact with both sides of the shallow trench isolation regions and extending towards a center;
spacers being in contact with the source/drain regions and having a predetermined depth inside the semiconductor substrate, the spacers being apart from each other at a predetermined distance;
a polysilicon layer filled between the spacers and functioning as a gate electrode;
a gate insulating layer formed to surround the bottom part of the polysilicon layer; and
source/drain extension regions formed by diffusion of ions from each spacer into the semiconductor substrate and being in contact with the adjacent source/drain regions,
the length of the polysilicon layer being controlled by the distance between the spacers.

2. A MOS (metal oxide semiconductor) transistor comprising:
a semiconductor substrate;
shallow trench isolation regions formed on either side of the semiconductor substrate and used for separation of elements;
source/drain regions being between both sides of the shallow trench isolation regions and extending towards a center;
a first oxide layer formed on the surface of the source/drain regions, and having gate, source, and drain patterns;
first spacers formed on a sidewall of the gate pattern of the first oxide layer on the source/drain regions;
second spacers formed on a sidewall of the first spacers and the source/drain regions in a predetermined depth towards the semiconductor substrate, the second spacers being apart from each other at a predetermined distance;
a polysilicon layer filled between the second spacers and functioning as a gate electrode;
a gate insulating layer formed to surround the bottom part of the polysilicon layer; and
source/drain extension regions formed by diffusion of ions from the second spacers into the semiconductor substrate and being in contact with the source/drain regions,
the length of the polysilicon layer being controlled by the distance between the second spacers.

3. The MOS transistor as claimed in claim 1, wherein the spacers or the second spacers are formed as deep as or deeper than the source/drain regions.

4. The MOS transistor as claimed in claim 2, wherein the spacers or the second spacers are formed as deep as or deeper than the source/drain regions.

5. The MOS transistor as claimed in claim 1, wherein the source/drain regions are doped as a p+ type region for a p-type MOS transistor, and as an n+ type region for an n-type MOS transistor.

6. The MOS transistor as claimed in claim 2, wherein the source/drain regions are doped as a p+ type region for a p-type MOS transistor, and as an n+ type region for an n-type MOS transistor.

7. The MOS transistor as claimed in claim 1, further comprising:
a silicide layer formed on the source/drain region and the polysilicon layer so as to reduce contact resistance.

8. The MOS transistor as claimed in claim 2, further comprising:
a silicide layer formed on the source/drain region and the polysilicon layer so as to reduce contact resistance.

9. A method for manufacturing a MOS (metal oxide semiconductor) transistor, comprising:
(a) forming shallow trench isolation regions, used for separation from other elements, on either side of a semiconductor substrate comprised of silicon, and implanting impurities to form source/drain regions being in contact with each shallow trench isolation region and extending towards a center;
(b) depositing a first oxide layer on a whole surface, etching a defined region of the center in a predetermined depth inside the semiconductor substrate, and forming spacers on a sidewall of each source/drain region;
(c) further etching the semiconductor substrate between the spacers to form a gate insulating layer;
(d) performing annealing on the whole resultant material, and implanting impurities from the spacers into the semiconductor substrate to form source/drain extension regions beneath each spacer, the source/drain extension regions being a shallow junction to the source/drain regions;
(e) depositing a polysilicon layer between the spacers to form a gate electrode; and
(f) depositing a second oxide layer on the whole surface, etching a region to be source and drain electrodes, and forming source and drain electrodes in the etched region through metallation.

10. A method for manufacturing a MOS (metal oxide semiconductor) transistor, comprising:
(a) forming shallow trench isolation regions, used for separation from other elements, on either side of a semiconductor substrate comprised of silicon, and implanting impurities to form source/drain regions being in contact with each shallow trench isolation region and extending towards a center;
(b) depositing a first oxide layer on a whole surface, etching a defined region of the center as deep as the source/drain regions, and forming first spacers on a sidewall of each source/drain region;
(c) etching a space between the first spacers in a predetermined depth inside the semiconductor substrate, and depositing a doped oxide layer to form second spacers on a sidewall of the first spacers;
(d) further etching the semiconductor substrate between the second spacers to form a gate insulating layer;
(e) performing annealing on the whole resultant material, and implanting impurities from the second spacers into the semiconductor substrate to form source/drain extension regions beneath each second spacer, the source/drain extension regions being a shallow junction to the source/drain regions;
(f) depositing a polysilicon layer between the second spacers to form a gate electrode; and
(g) depositing a second oxide layer on the whole surface, etching a region to be source and drain electrodes, and forming source and drain electrodes in the etched region through metallation.

11. The method as claimed in claim 9, wherein the spacers or the second spacers are formed as deep as or deeper than the source/drain regions.

12. The method as claimed in claim 10, wherein the spacers or the second spacers are formed as deep as or deeper than the source/drain regions.

13. The method as claimed in claim 9, wherein further comprising:
generating a source/drain extension region in shallow junction by using diffusion of ions or plasma doping other than the impurity-implanted spacers.

14. The method as claimed in claim 10, wherein further comprising:
generating a source/drain extension region in shallow junction by using diffusion of ions or plasma doping other than the impurity-implanted spacers.

15. The method as claimed in claim 9, wherein (e) comprises:
after deposition of the polysilicon layer, performing an etch-back process so as to make the top surface of the polysilicon layer deeper than the abutting spacers.

16. The method as claimed in claim 10, wherein (f) comprises:
after deposition of the polysilicon layer, performing an etch-back process so as to make the top surface of the polysilicon layer deeper than the abutting spacers.

17. The method as claimed in claim 9, wherein (b) comprises:
controlling the thickness of the spacers so as to control the distance between the spacers at a nanometer scale.

18. The method as claimed in claim 10, wherein (b) comprises:
controlling the thickness of the spacers so as to control the distance between the spacers at a nanometer scale.

19. The method as claimed in claim 9, wherein the thickness of the spacers or the second spacers is determined by a deposition thickness of the first oxide layer and an etching rate.

20. The method as claimed in claim 10, wherein the thickness of the spacers or the second spacers is determined by a deposition thickness of the first oxide layer and an etching rate.
